(19) United States
(12) Patent Application Publication
(10) Pub. No.: US 2005/0260812 A1
(43) Pub. Date: Nov. 24, 2005

(54) Memory cell having a trench capacitor and method for fabricating a memory cell and trench capacitor

(76) Inventors: Christian Kapteyn, Dresden (DE); Joern Regul, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/123,822

(22) Filed: May 6, 2005

(30) Foreign Application Priority Data
May 7, 2004 (DE) 10 2004 022 602.4

(51) Int. Cl. H01L 21/8234

(52) U.S. Cl. 438/243; 438/386

(57) ABSTRACT

A memory cell having a trench capacitor, a trench capacitor, and a method is disclosed. In one embodiment, the method for fabricating a trench capacitor with a first capacitor electrode, a first capacitor dielectric, a second capacitor electrode, a second capacitor dielectric and third capacitor electrode, includes connecting the first and third capacitor electrodes. The first and third capacitor electrodes are formed by conformal deposition methods, whereas the first capacitor dielectric, the second capacitor electrode and the second capacitor dielectric are formed by nonconformal deposition methods.

### CROSS-REFERENCE TO RELATED APPLICATIONS

This Utility Patent Application claims priority to German Patent Application No. DE 10 2004 022 602.4, filed on May 7, 2004, which is incorporated herein by reference.

### BACKGROUND

Memory cells of dynamic random access memories (DRAMs) generally comprise a storage capacitor and a select transistor. An information item is stored in the storage capacitor in the form of an electric charge which represents a logic 0 or 1. Driving the read or select transistor via a word line allows the information item stored in the storage capacitor to be read via a bit line. The storage capacitor has to have a minimum capacitance in order to reliably store the charge and allow the item of information which is read to be differentiated. The lower limit for the capacitance of the storage capacitor is currently regarded as being approx. 25 fF.

Since the storage density increases from memory generation to memory generation, the surface area taken up by the single-transistor memory cell has to be reduced from generation to generation. At the same time, the minimum capacitance of the storage capacitor has to be retained.

Up until the 1 MBit generation, both the read transistor and the storage capacitor were realized as planar components. Beyond the 4 MBit memory generation, the surface area taken up by the memory cell was reduced further by a three-dimensional arrangement of the storage capacitor. One possibility is to realize the storage capacitor in a trench. In this case, by way of example, a diffusion area that adjoins the wall of the trench and a doped polysilicon filling in the trench act as electrodes of the storage capacitor. The electrodes of the storage capacitor are therefore arranged along the surface of the trench. This increases the effective surface area of the storage capacitor, on which the capacitance is dependent, compared to the space taken up by the storage capacitor at the surface of the substrate, which corresponds to the cross section of the trench. The packing density can be increased further by reducing the cross section of the trench while at the same time increasing its depth.

In the past, numerous measures have been taken to increase the storage capacity of the trench capacitors. One measure is to scale the thickness of the storage dielectric. Furthermore, the surface area within the trench capacitor can be increased by wet-chemical widening of the trench structure (bottle etch). Furthermore, it is possible to increase the surface area within the trench by roughening, for example by coating with HSG-polysilicon.

Further approaches include minimizing the electron depletion of the capacitor electrodes by increasing the doping of the Si electrode material and/or using metal electrodes, with the result that, at the same time, the resistance of the electrodes can be drastically reduced. Also, the previous NO dielectric can be replaced by a high-k dielectric in order to increase the capacitance of the trench capacitor.

Furthermore, it is aimed to produce capacitor trenches with a greater depth. However, technical and economical limits are increasingly being reached in the current etching processes for fabricating trench capacitors, since, for example, the etching rate and the selectivity of the etch decrease with increasing depth. Consequently, the hard mask for etching the trench is extensively etched at the surface.

WO 2004/017394 describes a method for depositing a nonconformal dielectric layer by only partially forming a layer produced by an ALD (atomic layer deposition) process as a result of a process quantity of a precursor material being restricted and/or restricting the time of the deposition process.

### SUMMARY

Embodiments of the invention provide a memory, a method of making a memory, and a trench capacitor. In one embodiment, the invention provides a semiconductor substrate. A memory cell is formed in the semiconductor substrate. The memory cell includes a trench capacitor including a first capacitor electrode, and first capacitor dielectric, a second capacitor electrode, a second capacitor dielectric, and a third capacitor electrode. The first electrode is connected to the third electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1-6 illustrate a process involved in the fabrication of a trench capacitor in accordance with a first exemplary embodiment of the present invention.

FIG. 7 illustrates a step involved in an alternative method for fabricating a trench capacitor.

FIGS. 8-11 illustrate steps involved in completing the trench capacitor in accordance with the first exemplary embodiment of the invention.

FIG. 12 illustrates a view of the finished memory cell.

FIG. 13 illustrates a layout in an 8 F² cell architecture.

FIG. 14 illustrates the layers that have been applied.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the present invention provides a method which allows a trench capacitor with a high capacitance to be produced.

Furthermore, the present invention provides a trench capacitor of this type.

Further, the present invention a method for fabricating a memory cell having a trench capacitor, and provides a memory cell having a trench capacitor of this type.

According to one embodiment of the present invention, the method for fabricating a trench capacitor includes:
(a) providing a semiconductor substrate;
(b) etching a trench into a surface of the semiconductor substrate, producing a trench wall, the trench having a depth d which is measured with respect to the surface of the semiconductor substrate;
(c) forming a first capacitor electrode adjoining the trench wall;
(d) carrying out a method for depositing a first dielectric layer, in such a manner that a predetermined layer thickness of the first dielectric layer is produced on that region of the surface resulting in step (c) which is at a distance of at most d1 from the surface of the semiconductor substrate, and no dielectric layer is formed on that region of the surface resulting in step (c) which is at a distance of at least d3 from the surface of the semiconductor substrate;
(e) carrying out a method for depositing a layer of conductive material, in such a manner that a layer of the conductive material is formed on that region of the surface resulting in step (d) which is at a distance of at most d2 from the surface of the semiconductor substrate, and no conductive material is deposited on that region of the surface resulting in step (d) which is at a distance of at least d2 from the surface of the semiconductor substrate, d2 being less than d1, resulting in the formation of a second capacitor electrode;
(f) carrying out a method for depositing a second dielectric layer, in such a manner that a predetermined layer thickness of the second dielectric layer is produced on that region of the surface resulting in step (e) which is at a distance of at most d1 from the surface of the semiconductor substrate, and no dielectric layer is formed on that region of the surface resulting in step (e) which is at a distance of at least d4 from the surface of the semiconductor substrate; and
(g) forming a conformal layer of a conductive material, resulting in the formation of a third capacitor electrode, in such a manner that the first and third capacitor electrodes are connected to one another.

To carry out the method according to the invention, therefore, a capacitor trench is etched into the surface of a semiconductor substrate. Then, the first capacitor electrode is formed. This can be done, for example, by depositing a conformal metal layer.

In particular an ALD (atomic layer deposition) process can be used for this purpose. In this process, which is known per se, in a first process phase a first precursor material or a first precursor is fed to a process chamber in which the substrate is located. A process known as chemisorption causes the first precursor to accumulate on the substrate surface and the whole of the trench wall. In the process, the first precursor is generally modified. As soon as all the surface regions have been covered with the modified precursor material, the first process phase of deposition is concluded and a monomolecular individual sublayer of a modified precursor material has been deposited on the substrate surface and the trench wall surface.

Then, the undeposited residues of the first precursor material are removed from the process chamber by purging with an inert gas and/or being pumped out.

In a second phase, a second precursor material is introduced into the process chamber and is deposited virtually exclusively on the individual sublayer of the first precursor material. During this phase, the precursor materials are converted into the layer material. An individual layer (monolayer) of the layer to be produced is formed. After undeposited fractions of the second precursor material have been removed from the process chamber, one process cycle of the ALD process is over. The process cycle is repeated until a layer of predetermined layer thickness has been formed from the individual layers deposited each process cycle.

The ALD processes for producing conformal layers usually make use of the self-limiting character thereof; in this context, given a sufficient supply of the precursor materials, a complete covering layer (conformal liner) of virtually uniform layer thickness results irrespective of the quantity of precursor materials supplied, the inflow characteristics thereof and the diffusion and reaction dynamics of the precursor materials. Since the deposition of the precursor materials is restricted substantially by chemisorption but not by the dynamic, diffusion-determined processes, very good edge coverage results for ALD processes during deposition on nonplanar, patterned substrate surfaces.

In a following operation, a first dielectric layer is deposited nonconformally. More accurately, the deposited layer extends only as far as a defined depth of the trench, with a predetermined layer thickness, and no further dielectric material at all is deposited in a lower trench part.

This can be achieved in particular by modifying the ALD process described above. In the case of an NOLA (nonconformal liner ALD) process of this type, the first precursor material is supplied in such a manner that a complete layer of the first precursor material results in an upper region of the trench, whereas no precursor material accumulates in the lower region of the trench. A transition region, in which there is a coverage gradient, between the upper and lower trench regions is of only a short extent, in the present case approximately a few hundred nanometers, based on the typical trench depth. Systematic, targeted coverage of the trench wall surface of this nature from the substrate surface toward the rear side of the substrate usually results preferentially if at least one of the precursor materials have a low desorption coefficient and is supplied in a reduced quantity compared to the quantity required for complete coverage.

If the precursor material has a low desorption coefficient, the probability of a molecule of the precursor material which has already been adsorbed being removed, i.e., desorbed, again from the layer is very low. If, during an ALD process, a precursor material with a low desorption coefficient, corresponding to a high sticking coefficient, is provided, by way of example a trench which has been etched in a substrate surface is progressively covered over the depth starting from the substrate surface. In this case, the coverage is complete, apart from a short transition region, and has a uniform layer thickness.

A precondition for this is that the precursor material be supplied in only a limited quantity or that the deposition method be interrupted in good time prior to complete coverage and the chamber pressure in the process chamber be selected in such a way that sufficiently slow diffusion of the precursor material into the depth of the trench is ensured.

This can be achieved, for example, by the quantity or concentration of a precursor material in the process chamber, a deposition duration or control time of the precursor material and/or a process pressure in the process chamber being set appropriately during the deposition.

A nonconformal layer can be produced without time control of the deposition operation being required in particular by one of the precursor materials, preferably one with a high sticking coefficient, being supplied in a lower quantity or concentration than would be required for complete coverage.

The first dielectric layer is deposited in such a manner that a predetermined layer thickness is produced down to a depth d1 and no layer at all is produced beyond a depth d3. The difference between d3 and d1, i.e. the transition region with a layer thickness that is not clearly defined but adopts a value in the range between 0 nm and the predetermined layer thickness, is usually a few 100 nm, for example 100 to 1 000 nm.

Then, to form a second capacitor electrode, a nonconformal layer of a conductive material is deposited. This is in principle done using the same method as explained above, but using different precursors, so as to produce a conductive layer.

The second capacitor electrode extends to a depth d2, d2 being less than d1. No conductive material is deposited below d2. In the case of the conductive capacitor electrode, the layer thickness in the lower region within the trench, i.e. in the vicinity of depth d2, may be nonuniform, i.e., may decrease, as long as continuous electrical contact with the other regions of this conductive layer is ensured. However, it is important that the second capacitor electrode be completely surrounded by a layer thickness of the first and second dielectric layers which is such that it is electrically insulated from the other capacitor electrodes. Therefore, the first and second dielectric layers have to have a predetermined layer thickness down to a depth d1 which is greater than d2.

Then, a nonconformal second dielectric layer is deposited in such a manner that a predetermined layer thickness is present down to a depth d1 and no dielectric layer is formed beyond a depth d4. In particular, d4 may be equal to d3 for the first dielectric layer.

Finally, to form a third capacitor electrode, a conformal layer of a conductive material is deposited and connected to the first capacitor electrode.

The present invention therefore provides a method which allows a storage capacitor with an increased storage capacity to be provided by a suitable combination of conformal and so-called nonconformal deposition methods.

More specifically, the method according to the invention allows a plurality of capacitor electrodes to be arranged suitably in a capacitor trench and connected to one another in such a manner that the capacitance of the capacitor is increased.

A suitable combination of steps for conformal deposition and steps for nonconformal deposition therefore allow a multilayer structure to be realized within the capacitor trench, which ultimately increases the capacitance of the capacitor.

In particular by virtue of layers being deposited nonconformally, it is possible for layers deposited after the layers deposited nonconformally to be electrically connected to layers deposited before the layers deposited nonconformally without the layers having to be patterned. In particular, there is no need for layers which are located between two layers that are to be connected to one another to be covered or masked with a suitable layer and etched back in order to allow electrical contact.

Accordingly, the present invention allows a storage capacitor with an increased capacitance to be fabricated in a particular simple way and without complex method sequences.

Consequently, the aspect ratio of the resulting trench capacitor can be increased since, for example, there is no need for covering layers to be deposited and patterned in the narrow trench.

Examples of electrode materials include all conceivable electrode materials which can be deposited nonconformally in a controllable way. A controllable way means that a continuous layer is produced down to a defined depth, and no further material is deposited beyond the defined depth.

Examples of electrode materials include TiN, TiHfN, HfN, TiAlN, TaN, HfAlN and nanolaminates, i.e., multilayer structures comprising various layers of these materials which are only a few nanometers thick, or mixtures of these materials. However, the electrode materials do not necessarily have to contain metal. By way of example, it is also possible to use doped, in particular highly doped, polysilicon as electrode material.

Suitable precursor materials for metallic electrodes include TiCl₄, Ti(OC₂H₅), Ti(OCH(CH₃)₂)₄, HfCl₄, Hf-t-butoxide, Hf-dimethyl-amide, Hf-ethyl-methyl-amide, Hf-diethyl-amide or Hf(MMP)₄, TaCl₄, tri-methyl-aluminum (TMA) as first precursor material and NH₃ or H₂O and/or O₃ as second precursor material.

Suitable dielectric materials comprise all conceivable dielectric materials which can be deposited nonconformally in a controllable way. This in particular also means that the transition region between predetermined layer thickness and no deposited layer is as small as possible with respect to a typical trench depth. Examples of suitable dielectric materials include Al₂O₃, HfO₂, ZrO₂, SiO₂, Pr₂O₃ and nanolaminates or mixtures of these materials.

Suitable precursor materials for the dielectric layers include TMA, HfCl₄, Hf-t-butoxide, Hf-dimethyl-amide, Hf-ethyl-methyl-amide, Hf-diethyl-amide or Hf(MMP)₄, Si(NCO)₄, CH₃OSi(NCO)₃ as first precursor material and H₂O and/or O₃ and NH₃ as second precursor material.

After forming the third capacitor electrode, it is additionally possible to carry out the process of depositing a polysilicon filling. This process can be carried out, for example, if the third capacitor electrode has a thickness which does not completely fill the trench. For further processing of the trench capacitor, in particular the subsequent etchback steps, it is advantageous if a filled trench (for example filled with the material of the third capacitor electrode or also with polysilicon) is present, so that the surface for the etching chemistry to attack is well defined.

The material of the first and third capacitor electrodes, and in particular of the first, second and third capacitor electrodes, is preferably identical. However, it is also possible to use different materials in each case, for example, if a different thermal stability or other different properties are desired for the conductive layers.

It is preferable for the material of the first and second dielectric layers to be identical. However, in this case too it is also possible to use different materials in each case, for example if a different thermal stability or other different properties are desired for the dielectric layers. The layer thicknesses of the first and second dielectric layers may also be dimensioned as expedient and may be identical to or different from one another.

The difference between d and d1 is preferably less than 1 000 nm, and also preferably greater than 100 nm. It is desirable for this difference to be minimized, in order to maximize the capacitance for the resulting capacitor yet nevertheless to ensure that the second capacitor electrode is electrically insulated from the first and third capacitor electrodes.

The difference between d1 and d2 is preferably less than 1 000 nm, and also preferably greater than 100 nm. In this case too, it is desirable for this difference to be minimized, in order to maximize the capacitance of the resulting capacitor. On the other hand, the difference is preferably such that the second capacitor electrode only extends as far as a depth at which the sufficient layer thickness of the first and second dielectric layers is maintained.

Furthermore, it is provided that the above-described process for the conformal and nonconformal deposition be repeated in a suitable combination in order to realize an even greater number of capacitor electrodes within the capacitor trench.

In one embodiment, the present invention provides a method for fabricating a memory cell.

Moreover, the invention provides a trench capacitor, including a first capacitor electrode, a first capacitor dielectric, a second capacitor electrode, a second capacitor dielectric, a third capacitor electrode, which are each arranged at least partially in a trench, the first capacitor electrode adjoining a wall of the trench, and the first capacitor electrode being electrically conductively connected to the third capacitor electrode, and the second capacitor electrode being arranged in a space formed between the first and third capacitor electrodes and being electrically insulated from the first capacitor electrode by the first capacitor dielectric and the second capacitor electrode being electrically insulated from the third capacitor electrode by the second capacitor dielectric.

The trench preferably has a depth and a smallest diameter, with the ratio of depth to smallest diameter being greater than 20 and in particular greater than 40.

The present invention therefore provides a trench capacitor with a triple electrode arrangement and a particularly high aspect ratio. In other words, a trench capacitor with a high storage capacity can be provided with a particularly small demand for space.

When seen in plan view, capacitor trenches are not usually circular, but rather oval. This means that they have different two diameters along two different section directions. If the trench which is etched in the semiconductor substrate and all the trench parts have the same diameter, the smallest diameter corresponds to the smallest diameter or the smallest width of all the trench parts. On the other hand, if the uppermost trench part, at least in one direction, has a smaller diameter than the trench parts below it, the smallest diameter corresponds to the smallest diameter of the uppermost trench part.

According to the present invention, it is furthermore preferable for the material of the first and/or second capacitor electrodes to be a metal or a metal compound. This allows the conductivity of the corresponding capacitor electrode and, moreover, the capacitance of the storage capacitor to be increased, since no space charge regions are formed.

In another embodiment, the present invention provides a memory cell. A 3 nm thick SiO₂(oxide) layer 3 and a 220 nm thick Si₃N₄ layer 4 are applied to a surface 1 of a semiconductor substrate 2. Then, a 620 nm thick BPSG layer (not shown) is applied.

The BPSG layer, the Si₃N₄ layer 4 and the SiO₂ layer 3 are patterned in a plasma etching process using CF₄/CHF₃ in combination with a photolithographically produced mask (not shown), so as to form a hard mask. In a further plasma etching process using this hard mask as etching mask, trenches 5 are etched into the main surface 1 using HBr/NF₃, uncovering a trench wall 11 within each trench 5.

Then, the BPSG layer is removed by a wet etch using H₂SO₄/HF.

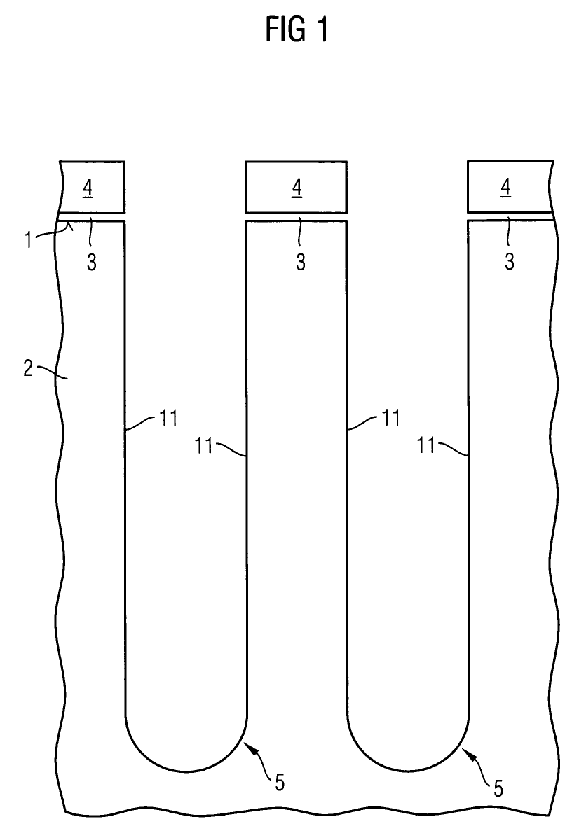

For example, the depth of the trenches 5 is 6.6 μm, the width of the trenches 5 is 100×250 nm, and the distance between the trenches is 100 nm. This results in the structure illustrated in FIG. 1.

The first capacitor electrode is produced in a subsequent step. In accordance with the first exemplary embodiment, the first capacitor electrode is realized by a metallic electrode 6, which is connected to the semiconductor substrate 2 via an n⁺-doped area 25. Alternatively, however, it is also possible for the first capacitor electrode to be realized in other ways, for example only by a n⁺-doped area.

To produce the n⁺-doped area 25, first of all, as is generally customary, the upper trench region, in which the insulation collar will subsequently be formed, has to be covered by a suitable covering material in order to prevent the dopant from diffusing out into this region.

By way of example, Al₂O₃ deposited by a nonconformal deposition process—as explained above—can be used as covering material.

Then, doping is carried out using known methods in the uncovered region of the trench wall 11.

This doping may be effected, for example, by depositing an arsenic-doped silicate glass layer in a layer thickness of 50 nm and a TEOS-SiO₂ layer in a thickness of 20 nm, followed by a conditioning step at 1 000° C. for 120 seconds. In the process, an n⁺-doped area is formed in the semiconductor substrate 2 through outdiffusion from the arsenic-doped silicate glass layer. Alternatively, it is also possible to carry out gas phase doping, e.g. using the following parameters: 900° C., 3 torr of tributylarsine (TBA) [33%], 12 minutes.

The arsenic-doped silicate glass layer and the TEOS-SiO₂ layer are removed again in an etching step using NH₄F/HF which is selective with respect to Si₃N₄ and silicon.

Then, the covering material for the insulation collar region is removed again.

Next, the first metallic capacitor electrode 6 is formed.

This electrode may be formed, for example, by TiN (titanium nitride) by the ALD process as described above, by first of all a first precursor gas, for example TiCl₄, being passed into the process chamber. Once the surface is saturated, a cleaning step is carried out, for example by introducing an inert gas and/or evacuating the process chamber. Next, the second precursor gas, for example NH₃, is introduced into the process chamber. A first atomic layer of the TiN layer is formed. Once again, a cleaning step is carried out, for example by introducing an inert gas and/or evacuating the process chamber.

The method, i.e., the introduction of first precursor gas and then second precursor gas, is repeated until the desired layer thickness of the TiN layer is achieved.

In the present example, a layer thickness of 5 to 10 nm is deemed appropriate for the first capacitor electrode 6.

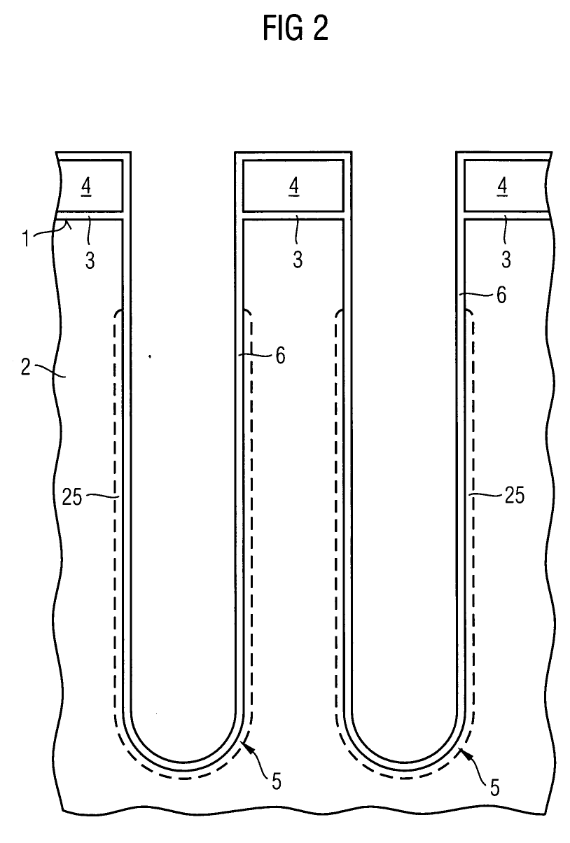

This results in the structure shown in FIG. 2.

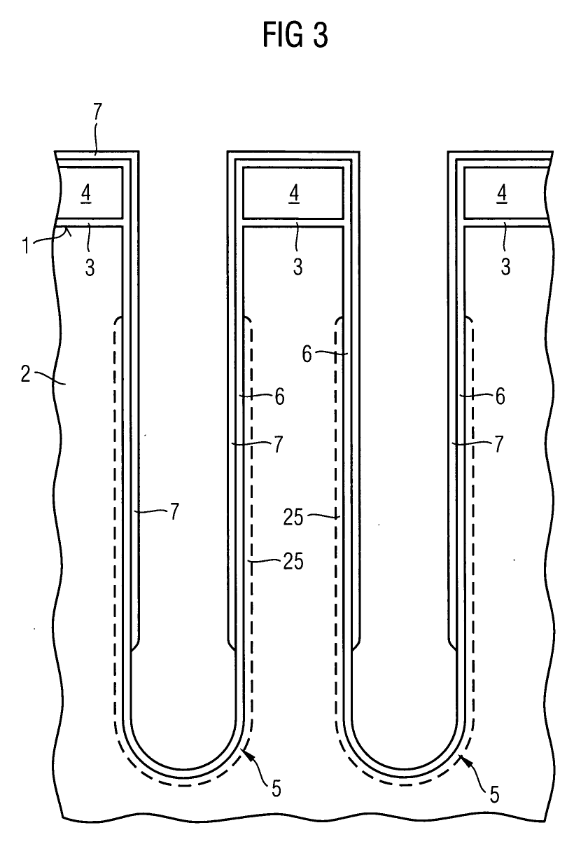

As illustrated in FIG. 3, then an approximately 4 to 5 nm thick Al₂O₃ layer 7 is deposited by a nonconformal deposition method, as explained above. This can take place, for example, using TMA (tetramethylaluminum) and H₂O or 03 gas as precursor gases. The depth d1 down to which the predetermined layer thickness of the Al₂O₃ layer extends is approximately 6 μm.

Alternatively, the dielectric layer 7 contains Al₂O₃, TiO₂, Ta₂O₅ or other known dielectric material which can likewise be deposited by a nonconformal method.

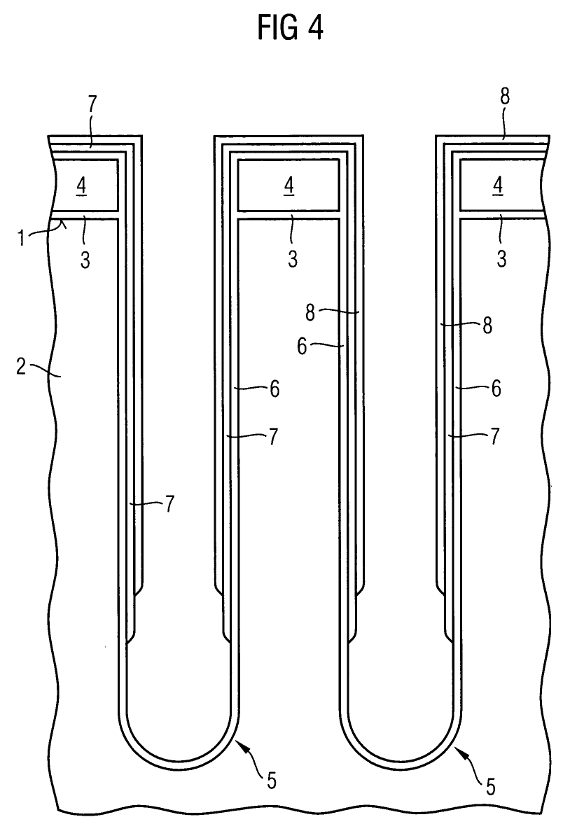

As illustrated in FIG. 4, a further 5 to 20 nm thick TiN layer 8 is then deposited by a nonconformal deposition method as second capacitor electrode. The depth d2 down to which the second capacitor electrode extends is approximately 5.5 μm.

Next, a further nonconformal deposition method is carried out, by which a second dielectric layer 9 is deposited. In this embodiment, the parameters are set to be precisely the same as those used in the deposition method for forming the first dielectric layer, resulting in the same depth and also layer thickness of the layer that is formed.

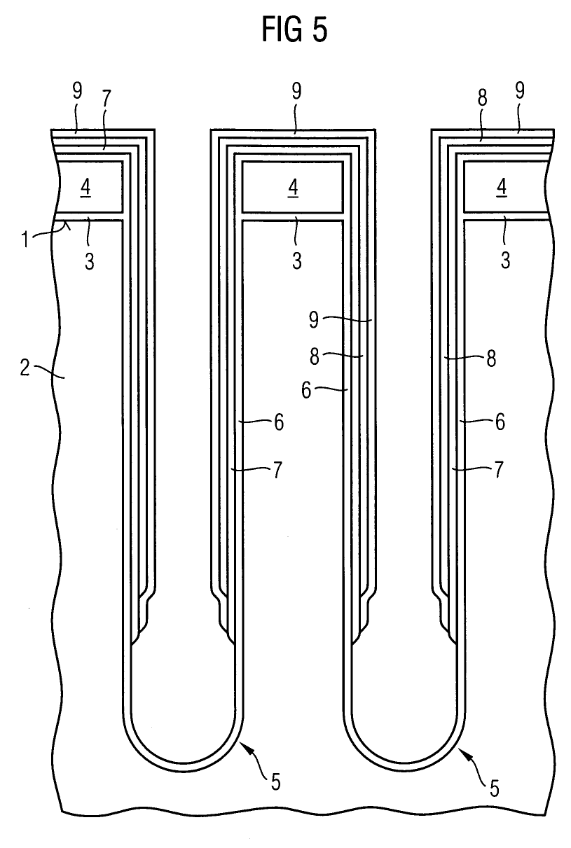

The result is the structure illustrated in FIG. 5.

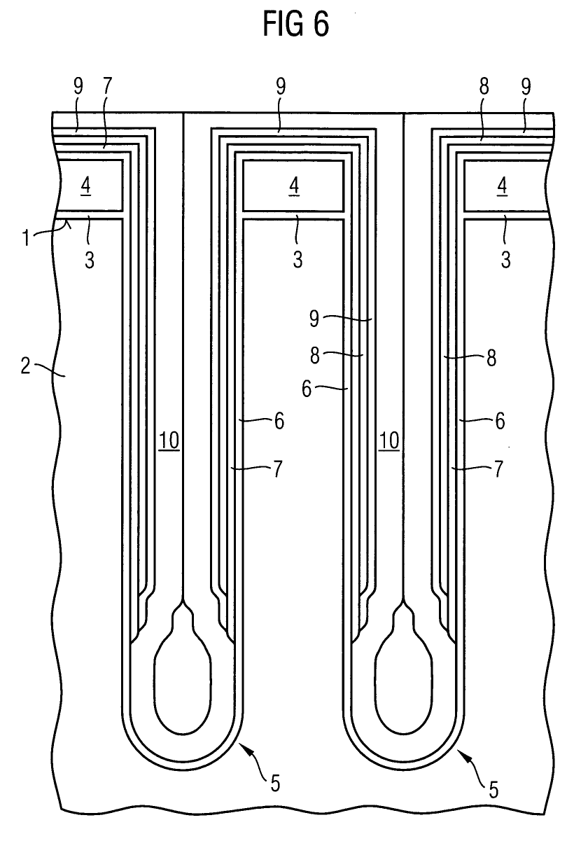

As illustrated in FIG. 6, a further TiN layer as third capacitor electrode 10 is then formed by a conformal deposition method. According to this exemplary embodiment, this TiN layer is formed in a layer thickness which is such that the trench is completely filled with the TiN layer in its upper part, whereas a void is formed in its lower part.

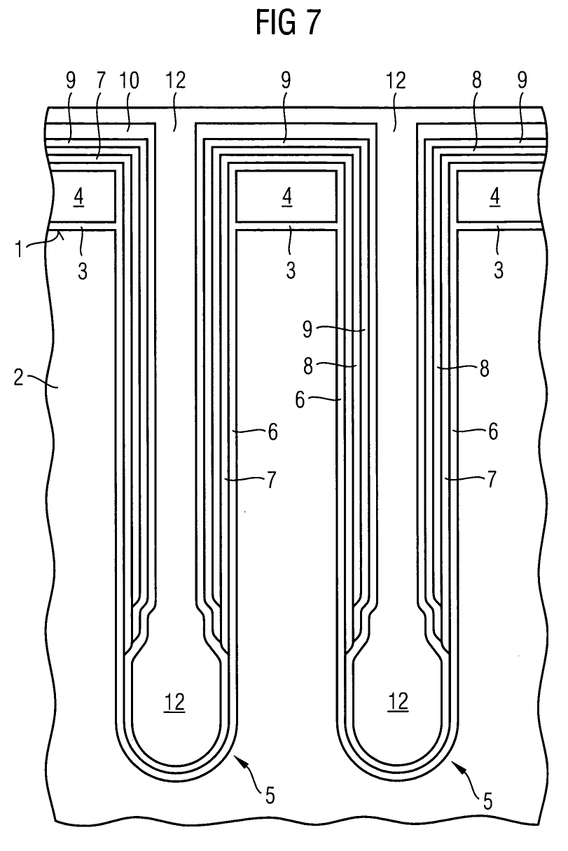

Alternatively, this TiN layer may also be formed in a lower thickness, and then a polysilicon filling 12 can also be deposited using known methods. This is illustrated in FIG. 7.

Next, the applied layers are etched back in a suitable way. The starting point is the trench structure illustrated in FIG. 6.

First of all, the third capacitor electrode layer 10 is etched selectively with respect to the dielectric layer 9 beneath it down to a depth of 1 300 nm, for example, by a wet-chemical etch using ammonia and hydrogen peroxide (H₂O₂).

After this, the second dielectric layer 9 is etched selectively with respect to the second capacitor electrode layer beneath it, down to a depth of 1 150 nm.

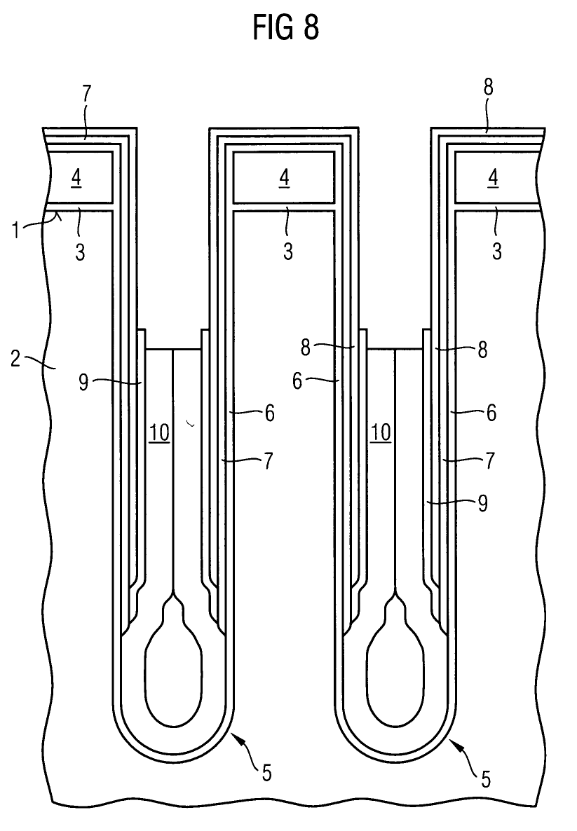

The result is the structure illustrated in FIG. 8.

Next, an illustration filling 13 is introduced. It can be introduced, for example, by deposition of SiO₂, for example by a TEOS or HDP method or an alternative method for applying a dielectric material, followed by dry-chemical or wet-chemical etchback. The insulation filling can be etched back, for example, to a depth of approximately 1 000 nm below the surface 1 of the silicon substrate 2.

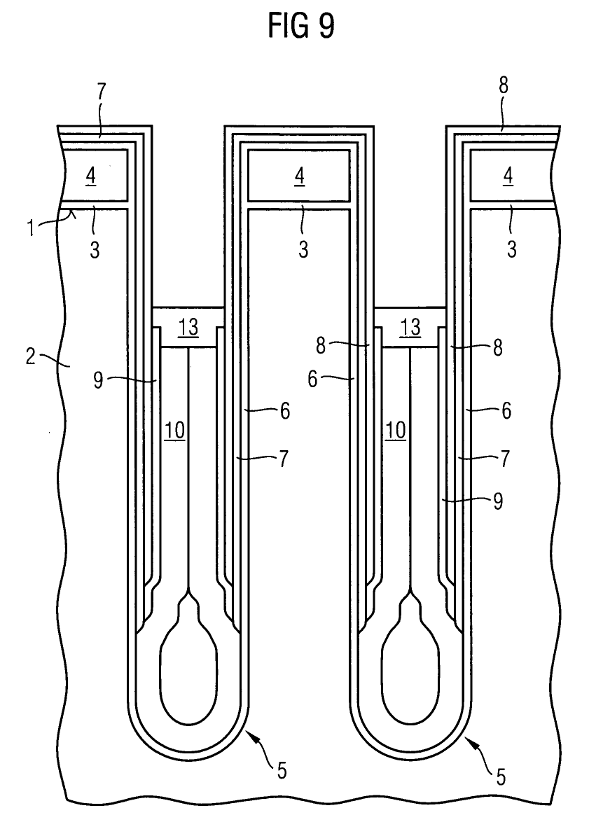

This results in the structure illustrated in FIG. 9.

Next, the second capacitor electrode layer 8, the first dielectric layer 7 and the first capacitor electrode layer 6 are etched, in each case selectively with respect to one another, in successive steps. The second capacitor electrode layer 8, which is intended for connection to the first source/drain region of the select transistor, is etched back less far than the first capacitor electrode layer 6 and the dielectric layer 7. In particular, it is provided that the second capacitor electrode layer 8 is etched back down to a depth of 900 nm, whereas the first capacitor electrode layer 6 and the first dielectric layer 7 are etched back to the same height as the upper end of the insulation filling 13, i.e., to a depth of approximately 1 000 nm below the surface 1 of the silicon substrate 2.

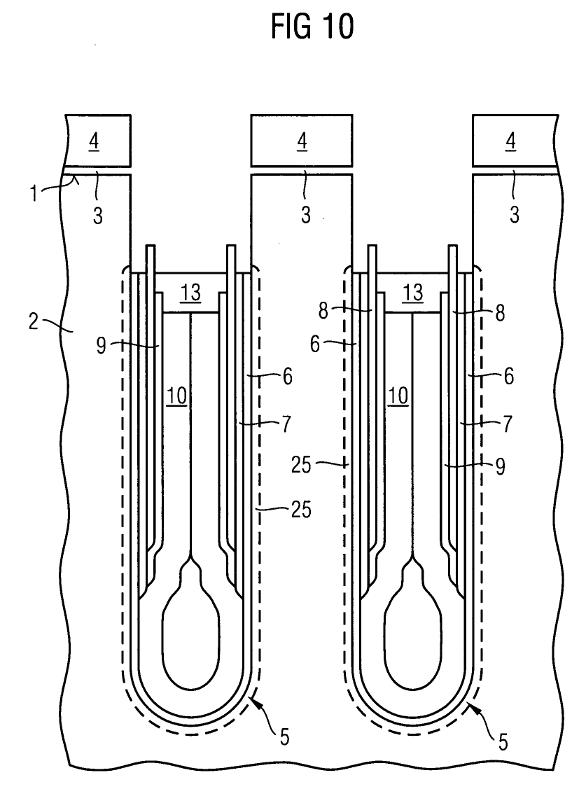

This results in the structure illustrated in FIG. 10.

The further method involved in fabricating a storage capacitor and a select transistor connected to it for a conventional memory cell structure will now be explained. This method and the memory cell structure are generally known and are described purely for the sake of completeness. It will be clear that the trench capacitor according to the invention can also be realized using any other desired cell concepts.

To define the insulator collar 14, an SiO₂ layer is deposited conformally in a layer thickness of 25 nm. The deposited SiO₂ layer 14 is then etched anisotropically, thereby producing the SiO₂ insulation collar in the upper part of the trenches. The purpose of the insulation collar 14 is to suppress a parasitic transistor which would otherwise form at this point.

Next, an n⁺-polysilicon layer 15 is deposited, thereby filling the trench of the storage capacitor in the collar region. To prepare for the buried contacts that are subsequently to be produced, the polysilicon is etched back to approximately 120 nm below the surface 1 of the semiconductor substrate.

To uncover the buried contact surfaces, the SiO₂ collar region 14 is etched away in the upper region.

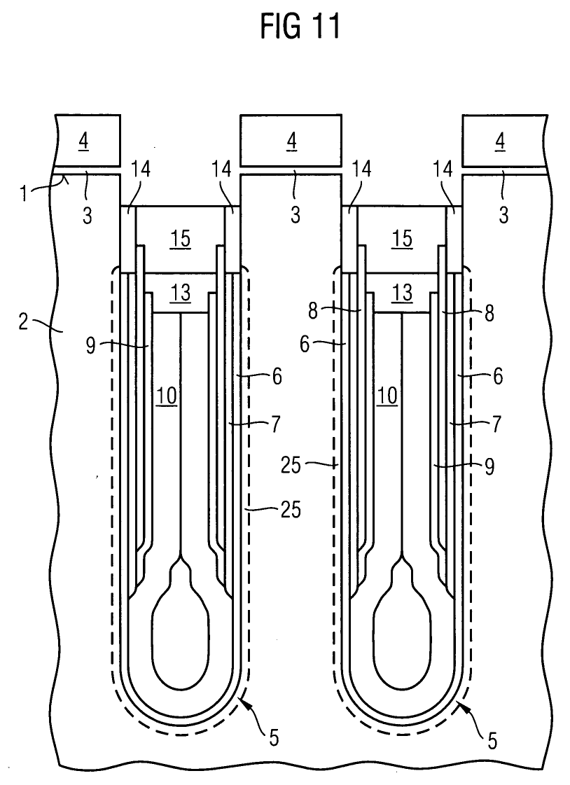

This results in the structure illustrated in FIG. 11.

To complete the buried contacts, after the open silicon surfaces have been nitrided, an n⁺-polysilicon layer is then deposited again and planarized down to the surface of the Si₃N₄ layer 4 by chemical mechanical polishing. The deposited polysilicon layer is etched back to approx. 40 nm below the surface 1 (recess 3 etch).

Next, to define active areas, insulation structures 16, which laterally delimit the active areas, are produced. For this purpose, a photolithographically produced mask (not shown) is formed, covering the active areas. This is followed by a nonselective etching step using CHF₃/N₂/NF₃, in which Si₃N₄, SiO₂ and polysilicon are etched. The etching depth in this step corresponds to the depth of the trench isolation. Then, the photoresist mask is removed. After that, a thin thermal SiO₂ layer is produced on silicon by oxidation.

This is followed by HDP deposition (high density plasma process) of SiO₂ in a thickness of 250 nm. The insulation structure 16 is completed by chemical mechanical polishing down to the surface of the Si₃N₄ layer 4, an etching step in H₃PO₄, which attacks Si₃N₄, followed by an etching step using DHF (dilute hydrofluoric acid), which attacks SiO₂, and the layers of the hard mask, the Si₃N₄ layer 4 and the SiO₂ layer 3 are removed.

Then, a screen oxide is formed by sacrificial oxidation. Photolithographically produced masks and implantations are used to form n-doped wells, p-doped wells and to carry out threshold voltage implantations in the region of the periphery and the select transistors of the cell array. Furthermore, high-energy ion implantation is carried out to form an n⁺-doped area 22, which connects the n⁺-doped substrate regions 25 of adjacent lower capacitor electrodes 6 to one another (known as “buried well implant”).

Then, the transistor is completed by generally known method steps, by respectively defining the gate oxide and the gate electrodes 17, corresponding interconnects and the source/drain electrodes 18, 19. The memory cell arrangement is then completed in a known way by forming further metallization levels.

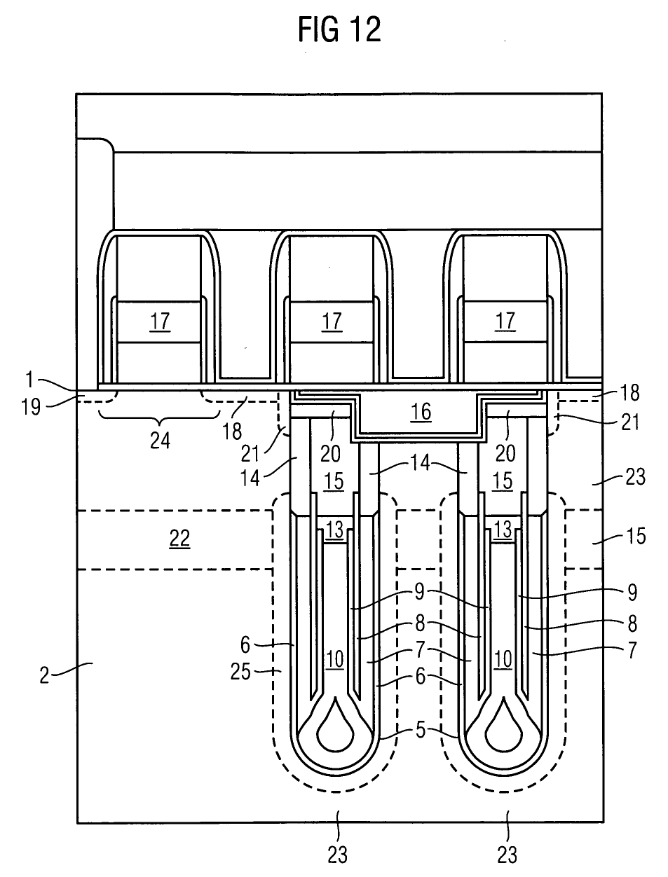

FIG. 12 diagrammatically depicts the resulting memory cell. The trench capacitors 23 with first capacitor electrode 6, first dielectric layer 7, second capacitor electrode 8, second dielectric layer 9 and third capacitor electrode 10 are in each case arranged in the trenches 5. The third capacitor electrode 10 is conductively connected to the first capacitor electrode 6. Consequently, the electrode surface area and therefore the storage capacity can be increased considerably compared to conventional storage capacitors.

The second capacitor electrode 8 is connected to the first source/drain electrode 18 of the select transistor 24 via the polysilicon area 20 and the doped region 21. The conductivity of the conductive channel which forms between first and second source/drain electrodes 18, 19 is controlled by means of the gate electrode 17.

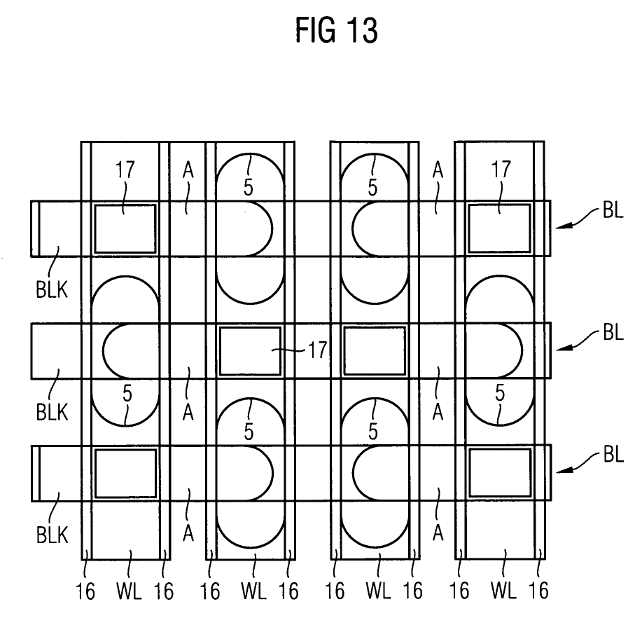

FIG. 13 illustrates, by way of example, a layout for an 8 F² cell architecture of the memory cells described. The memory cell arrangement has, for each memory cell, a storage capacitor arranged in one of the trenches 5 and a planar select transistor. Each memory cell requires a space of 8 F², where F is the minimum feature size that can be produced in the respective technology. The bit lines BL run in strip form and parallel to one another in plan view. The width of the bit line BL in each case being F, and the distance between them likewise being F. The word lines WL, which likewise have a width of F and a distance between them of F, run perpendicular thereto in plan view. Active areas A are arranged below the word lines WL and bit lines BL, with two word lines WL crossing above each active area. The active areas A are in each case arranged offset with respect to one another beneath adjacent bit lines BL. A bit line contact BLK, which allows electrical connection between the respective bit line BL and the active area A, is arranged in the center of the active areas A. The trenches 5 are in each case arranged beneath the word lines WL. The gate electrode 17 of the associated select transistor is in each case formed within the active areas at the crossing point between one of the bit lines BL and one of the word lines WL.

The active areas A in each case extend between two trenches 5. They comprise two select transistors, which are connected to the associated bit line BL via a common bit line contact BLK. The information is read out of the storage capacitor located in one or other of the trenches 5 depending on which of the word lines WL is driven.

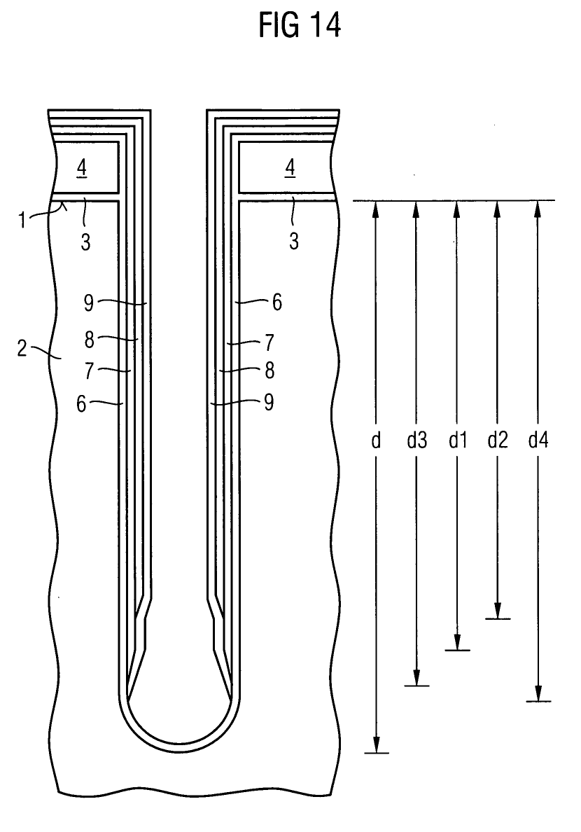

FIG. 14 diagrammatically depicts the depths down to which the nonconformally deposited layers in each case extend.

The trench 5 which has been etched in the semiconductor substrate 2 has a depth d, i.e. the vertical distance between the base and the surface 1 of the semiconductor substrate 2 is d. The first dielectric layer 7 and the second dielectric layer 9 have a predetermined layer thickness down to a depth d1, the layer thickness being measured with respect to the layer formed previously. In other words, the first and second dielectric layers are deposited conformally down to a depth d1. Beyond a depth d3, no further material of the first dielectric layer is deposited, and beyond a depth d4, no further material of the second dielectric layer is deposited. It is preferable for d3 to be equal to d4. The layer 8 of conductive material is deposited in such a manner that it extends down to a depth d2. The variables d1 and d2 are such that the layer 8 is completely surrounded by dielectric material. In other words, d2 is less than d1.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method of making a memory comprising:
providing a semiconductor substrate; and
forming a memory cell in the semiconductor substrate, the memory cell having a trench capacitor including a first capacitor electrode, and first capacitor dielectric, a second capacitor electrode, a second capacitor dielectric, and a third capacitor electrode, including connecting the first electrode to the third electrode.

2. The method of making a memory cell comprising:
forming the first capacitor electrode and the third capacitor electrode by a conformal deposition method; and
forming the first capacitor dielectric, the second capacitor electrode and the second capacitor dielectric by a nonconformal deposition method.

3. The method of claim 1, comprising:
making the first capacitor electrode and the third capacitor electrode from the same material.

4. The method of claim 1, comprising:
making the second capacitor electrode out of metal.

5. The method of claim 1, further comprising:
forming a select transistor associated with the memory cell.

6. The method of claim 5, comprising wherein the select transistor is configured to include a first source/drain electrode, and second source/drain electrode, a conductive channel and a gate electrode, wherein the second capacitor electrode is electrically coupled to the first source/drain electrode.

7. A method for fabricating a trench capacitor used in a memory cell, comprising:
providing a semiconductor substrate;
etching a trench into a surface of the semiconductor substrate producing a trench wall.
forming a first capacitor electrode adjoining the trench wall;
depositing a first dielectric layer;
depositing a layer of conductive material configured to form a second capacitor electrode;
depositing a second dielectric layer; and
forming a conformal layer of a conductive material resulting in the formation of a third capacitor electrode, configured to connect the first capacitor electrode to the third capacitor electrode.

8. The method of claim 7, comprising forming the first capacitor electrode by doping the substrate region adjoining the trench wall.

9. The method of claim 7, comprising forming the first capacitor electrode via conformal deposition of a metal layer.

10. The method of claim 9, further comprising depositing a polysilicon filling.

11. A method for fabricating a trench capacitor, comprising the steps of:
providing a semiconductor substrate;
etching a trench into a surface of the semiconductor substrate producing a trench wall, the trench having a depth d which is measured with respect to the surface of the semiconductor substrate;
forming a first capacitor electrode adjoining the trench wall in a first region;
depositing a first dielectric layer, in such a manner that a predetermined layer thickness of the first dielectric layer is produced on the first region is at a distance of at most d1 from the surface of the semiconductor substrate, and no dielectric layer is formed the first region which is at a distance of at least d3 from the surface of the semiconductor substrate;
depositing a layer of conductive material, in such a manner that a layer of the conductive material is formed on the first region which is at a distance of at most d2 from the surface of the semiconductor substrate, and no conductive material is deposited on the first region which is at a distance of at least d2 from the surface of the semiconductor substrate, d2 being less than d1, resulting in the formation of a second capacitor electrode;
carrying out a method for depositing a second dielectric layer, in such a manner that a predetermined layer thickness of the second dielectric layer is produced on the first region which is at a distance of at most d1 from the surface of the semiconductor substrate, and no dielectric layer is formed on the first region which is at a distance of at least d4 from the surface of the semiconductor substrate; and
forming a conformal layer of a conductive material, resulting in the formation of a third capacitor electrode, in such a manner that the first and third capacitor electrodes are connected to one another.

12. The method as claimed in claim 11, comprising of forming the first capacitor electrode via doping the substrate region which adjoins the trench wall.

13. The method as claimed in claim 11, comprising of forming the first capacitor electrode comprises the step of conformal deposition of a metal layer.

14. The method of claim 11 comprising depositing a polysilicon filling.

15. The method of claim 11, comprising, wherein the material of the first capacitor electrode and the third capacitor electrode is identical.

16. The method of claim 11 comprising, wherein the material of the first, second and third capacitor electrodes is identical.

17. The method of claim 11 comprising, wherein the material of one capacitor electrode, selected from the first, second and third capacitor electrodes, is different than the material of at least one of the other capacitor electrodes.

18. The method of claim 11 comprising, wherein the material of the first and second dielectric layers is identical.

19. The method of claim 11 comprising, wherein the material of the first dielectric layer and of the second dielectric layer differ from one another.

20. The method of claim 11, wherein the difference between d and d1 is less than 1 000 nm.

21. The method of claim 11 comprising, wherein the difference between d and d1 is greater than 100 nm.

22. The method of claim 11 comprising, wherein the difference between d1 and d2 is less than 1 000 nm.

23. The method of claim 11 comprising, wherein the difference between d1 and d2 is greater than 100 nm.

24. The method of claim 11, comprising forming a select transistor with first source/drain electrode, second source/drain electrode, conductive channel and gate electrode, the second capacitor electrode being electrically conductively connected to the first source/drain electrode of the select transistor.

25. A trench capacitor, comprising;
a first capacitor electrode;
a first capacitor dielectric;
a second capacitor electrode;
a second capacitor dielectric;
a third capacitor electrode, which are each at least partially arranged in a trench formed in a semiconductor substrate, the first capacitor electrode adjoining a wall of the trench, and the first capacitor electrode being electrically conductively connected to the third capacitor electrode, and the second capacitor electrode being arranged in a space formed between the first and third capacitor electrodes and being electrically insulated from the first capacitor electrode by the first capacitor dielectric and from the third capacitor electrode by the second capacitor dielectric; the first capacitor dielectric being formed from a first dielectric layer, which has a predetermined layer thickness on a region extending as far as a distance of d1 from a surface of the semiconductor substrate, and not being formed on a region beyond a distance of d3 from the surface of the semiconductor substrate;
the second capacitor electrode being formed from a layer of a conductive material which is formed on a region extending as far as a distance d2 from the surface of the semiconductor substrate, but no conductive material being formed on a region beyond a distance of d2 from the surface of the semiconductor substrate, d2 being less than d1; and
the second capacitor dielectric formed from a second dielectric layer having a predetermined layer thickness on a region extending as far as a distance d1 from the surface of the semiconductor substrate and not being formed beyond a distance d4 from the surface of the semiconductor substrate.

26. The trench capacitor claim 25, wherein the trench has a depth and a smallest diameter, and the ratio of depth to smallest diameter is greater than 20.

27. The trench capacitor claim 26, wherein the ratio of depth to smallest diameter is greater than 40.

28. The trench capacitor of claim 25, wherein the first capacitor electrode and the third capacitor electrode are made from the same material.

29. The trench capacitor of claim 25, wherein the first, second and third capacitor electrodes are made from the same material.

30. The trench capacitor of claim 25, wherein the material of the first capacitor electrode is a metal or a metal compound.

31. The trench capacitor of claim 25, wherein the material of the second capacitor electrode is a metal or a metal compound.

32. The trench capacitor of claim 25, comprising wherein the trench capacitor is configured as a memory cell and further comprises a select transistor with first source/drain electrode, second source/drain electrode, conductive channel and gate electrode, the second capacitor electrode being electrically conductively connected to the first source/drain electrode of the select transistor.

33. A memory comprising:
a semiconductor substrate; and
a memory cell formed in the semiconductor substrate, the memory cell having a trench capacitor including a first capacitor electrode, and first capacitor dielectric, a second capacitor electrode, a second capacitor dielectric, and a third capacitor electrode, connecting the first electrode is connected to the third electrode,
wherein the first capacitor electrode and the third capacitor electrode are formed by a conformal deposition method, wherein the first capacitor dielectric, the second capacitor electrode and the second capacitor dielectric are formed by a nonconformal deposition method; and
means for selecting the memory cell.
